(19) United States
(12) Patent Application Publication
(10) Pub. No.: US 2015/0091547 A1
(43) Pub. Date: Apr. 2, 2015

(54) METHOD, DEVICE, SENSOR AND ALGORYTHM FOR DETECTION OF DEVICES STEALING INFORMATION FROM ATM DEVICES

(71) Applicants: Vasil Stefanov Vasilev, Sofia (BG); Dimitar Nikolov Doychev, Sofia (BG)

(72) Inventors: Vasil Stefanov Vasilev, Sofia (BG); Dimitar Nikolov Doychev, Sofia (BG)

(21) Appl. No.: 14/390,684

(22) PCT Filed: Mar. 22, 2013
(86) PCT No.: PCT/BG2013/000007

§ 371 Date: Oct. 3, 2014

(30) Foreign Application Priority Data
Apr. 3, 2012 (BG) 111188

(51) Int. Cl. G01R 23/15; G07F 19/00

(52) U.S. Cl. CPC G01R 23/15; G07F 19/207
USPC 324/76.45

(57) ABSTRACT

Method for detection of skimming devices comprising detecting electromagnetic emissions by sensors of the invention located inside of ATM. Electromagnetic emission is monitored in broad band of 10 kHz to 30 MHz and narrow band, and only one determined frequency is passed through filters in the narrow band, and sensors' output is analyzed and processed according to algorithm of the invention. Alarm signal is generated upon achieving pre-assigned threshold chosen so that discriminating between useful signal and interference is not obstructed. The method is implemented by device comprising sensors for detecting electromagnetic emissions, microcontroller for controlling the sensors, master microcontroller for processing of sensors' output, and notifying module for sending signals to control center. According to the invention sensor is provided for detecting electromagnetic emissions comprising receiving, regulating, filtering and converting parts.

### FIELD OF INVENTION

The present invention relates to a method for detection of devices stealing information (skimming devices) from banking automatic teller machines (ATM), to a device, sensor and algorithm for use with the method.

### BACKGROUND OF THE INVENTION

Development of banking operations led to emerging of automatic machines for drawing and depositing of money by clients of the banks without the necessity for these clients to stand in a queue in a banking office in order to do this. Furthermore using these banking machines allows teller operations to be carried out regardless of the working hours of the bank. These automatic teller machines (ATMs, banking automations) are installed on easily accessible public places in order to facilitate the clients of the bank but this allows also the access of persons with bad intentions who try to use unlawfully and to criminal purposes the information written on the bank cards used with the banking machines. To this purpose new types of devices (skimming devices) are being invented ceaselessly that are connected externally to the automatic teller machine and that “steal” the information from the bank cards of the users.

Generally the “skimming” itself should be regarded as two separate processes. The first one is reading the content of the magnetic card, storing this content and transmitting it to a distant recording device. The second process is acquiring (finding out) the PIN code of the bank card and again storing this information. Not least is the timing synchronization of both kinds of information. The standards ISO 7811, ISO 7812, ISO 7813 define very precisely the mechanical and electrical parameters of the magnetic bank cards, location of the separate recording tracks, density of recording, its structure, type of encoding the separate symbols etc.

For the purposes of the present specification we'll discuss only the aspects relating to the protection of the bank cards from unlawful intervention.

Although there are three magnetic tracks physically located on the bank card, in order to clone the card it is sufficient to read the information from the second track only. Recording on the second track has the lowest density—75 symbols per inch. This facilitates the mechanical embodiment of the reading device (only one magnetic head is necessary) as well as the storage of the information.

Reading is carried out by means of magnetic head located on a precisely determined spot coinciding with the location of track 2 (10.5 mm away from the end of the bank card). There follows an amplifier with sufficiently high gain and suitable frequency band and a recording or retransmitting unit. As recording units most often are used MP3 players in regime “voice recording”. This is a cost saving and highly technological approach that consequently requires only the analysis of the recording and its decoding. Nowadays this is the most popular skimming method. As its drawback could be mentioned the relatively large size of the electronics but it may be concealed by a false panel resembling some decorative element of the automatic teller machine.

Many developments exist where the recording process is carried out by a specialized hardware. From the point of view of the technical schematics such software comprises a micro controller and a non-volatile memory. These devices are mechanically much smaller, with much lesser consumption of energy and accordingly they may be concealed much easier. Their use is limited by their covert selling, very high price, necessity of using specialized software to read the information and not least—the limited memory volume accommodating a limited number of records. An important problem is as well the great number of records that cannot be decoded.

A third approach exists too that consists in transmitting the amplified signal by means of high frequency transmitter to a device in which must be recorded the information. Use is made of transmitters working at very high frequency (400 MHz-2 GHz) in order to decrease the consumption, the antenna size and limitations of broadcasting. Usually a MP3 player is used to record the received information, this MP3 player being concealed behind a false panel but this time much further from the card slot. Quite often for recording is used the voice canal of a recording micro camera by means of which is monitored the keyboard for entering the PIN code. This method is very effective and does not require a serious engineering resource.

The second process is acquiring the PIN code. Two approaches are used—monitoring the keyboard by means of a concealed miniature camera or putting a false keyboard on top of the original one.

The cameras have a SMOS sensor, an integrated Flash memory and provide a long recording (up-to 10-12 hours depending on the energy supply elements and volume of the memory). The concealing is done most often by their mounting in bands resembling in shape and color some element of the ATM. They are mounted most frequently above the screen or by the side thereof, the lens being directed toward the keyboard for entering the PIN code. This type of cameras are not sufficiently sensitive and this limits their use at places that are not well illuminated (e.g. at night). Another problem is also covering the keyboard with the hand or some object by the user who enters the PIN code.

These problems are not present in the method using the false keyboard. The latter resembles very nearly the original one and it is mounted on top of the original keyboard. Any push on a button is recorded in a non-volatile memory. The consumption of energy by these devices is insignificant and the memory volume is sufficient to accommodate a very large number of records.

In view of this there is a constant need to invent methods and devices for detection of such skimming devices and prevent the theft of confidential information from the bank cards of the users.

A lot of documents disclosing such methods and devices are known, for example:

GB 0427810.7 discloses an anti-skimming device for use with banking machines having two or more optical sensors measuring the light falling thereon. Generally it is counted on the skimming device being concealed by a false non-transparent panel screening the sensor. When the light falling on any of the sensors is reduced under a pre-determined threshold the controller generates a signal triggering an alarm and stops the functioning of the automatic teller machine. The drawbacks of this solution are that in practice the false panels may be sufficiently transparent or, at least sufficiently transparent in their part covering the sensor. Besides the sensors are overt and a light source (LED) may easily be mounted in front of them which will render the protection absolutely ineffective. Surely in this manner cannot be detected also the contemporary miniature skimming devices mounted at the card slot. Not least it is not clear how the device will work in conditions of diminished light or at night.

PCT/EP2007/054095 discloses a cash-point comprising detecting device. The protection method here consists in scanning the frequency band between 100 MHz and 2000 MHz in which usually operate the transmitting devices with low power used for directly transmitting read data or stored data. The device continuously scans the predetermined frequency band and upon detecting a broadcast with level above the predetermined threshold it triggers an alarm and stops the operations of the cash-point. A lot of measures are taken to filter the frequencies of mobile operators, some ground services, unoccupied frequencies used for signals of mechanical devices (car-alarms and others) etc. which may be obstructive to the stable operation of the scanner. All this complicates the scanner and makes it unnecessarily expensive. Besides the broadcasting frequencies may be much higher or lower than the controlled ones. Data packets may be much shorter and the detector may not be able to recognize them as skimmed data. It is not clear what would be the conduct of the scanner in case of modulation with a noise spectrum. Not least should be mentioned that the method using data transmission is only one of the skimming methods and at that the least frequently used up-to the moment.

EP 1530150 B1 discloses a device intended to detect the presence of an object in the space around the entrance slot of the magnetic card reader. It represents an emitter and a receiver of ultrasound frequency (around 40 Hz) and technical circuitry detecting any change of the parameters of the medium between them. A number of measures are taken to diminish the interfering factors but in spite of this the drawbacks of the method are numerous. Even if the system is very sensitive it will be very difficult to detect unambiguously a small object and increasing the sensitivity will surely result in diminishing its stability and multiplication of the invalid alarm events.

WO 2010/123471 A1 discloses a method using the principle of volumetric capacitive sensor. Its purpose is again to detect an object put near the card slot but instead of ultrasound it uses electromagnetic emission with frequency around 300 Hz. A complicated algorithm for self-calibration is described aiming at adaptation to the existing mechanical characteristics of the particular automatic teller machine. A parameter called “compensation difference” is defined that indicates the level under which no alarm signal will be generated yet. However this method cannot detect the contemporary skimmers that keep becoming smaller.

US 2011/0006112 A1 disclosed a method belonging to the so called “active” protection methods. The aim is to induct an interfering signal in the unlawfully mounted reading head, the level of this interfering signal being several times higher than the one of the useful signal. As a consequence of this the stored information would be strongly distorted, with missing fragments and its processing will be very difficult. There are comments also relating to broadcasting of a combined signal—white noise mixed with F/F2 encoded accidental signal which could make the method even more effective. However the problems of the practical effective implementation of the method are many as well. On one hand there exists quite a real danger of damaging the original bank card if the intensity of the interfering magnetic field is too high and this is especially valid for LoCo cards (with low coercivity). Because of this the strength of the interfering magnetic field is chosen as a compromise and this decreases the effectiveness of this method. Besides in view of the fact that the interference is inducted mainly in the magnetic head and the cable connecting this head to the preamplifier, it is sufficient to screen them well in order to counteract effectively this protection. If all above mentioned measures are taken (screening of the head, short and screened connecting cable, preamplifier with a differential input) the information obtained in unlawful manner will have quite high noise level but just the same it will be quite capable of being analyzed and decoded. In case some programming methods for filtering are applied (for which exist quite a big number of easily obtained software products) this method would have almost nonexistent protective effect.

KR20100072606 (A) discloses an anti-skimming device for ATM and the object of invention is to prevent the copying of a bank card. The protection method is a combination of detection of a false element with magnetic head mounted at the card slot and mechanical part that pulls into the automatic teller-machine's interior the existing decorative element (the original card slot or so called “mouth”). The subject of the patent is exactly this mechanical part (applicable to a particular type of ATMs only). The sensors detecting the presence of an additional, falsified “mouth” are mounted on the inside wall of the teller machine and control the exterior side of the bank card slot (“mouth”). These could be of various types (optical, ultrasound etc) and a control signal is generated and sent to an electrical motor drive upon meeting determined conditions. By means of a suitable mechanical transmission the rotary motion of the electrical motor drive is converted to a linear displacement and the whole reading module of the automatic teller machine is brought into its interior. If the false mouth is bigger in size it could get separated from the teller machine. If its size is smaller, it will be brought into the teller machine's interior. In any case the teller machine will not be at the disposal of the clients for carrying out banking operations. The disadvantage of this method consists in the fact that it could not be widely applied because it requires a serious mechanical remaking of the automatic teller machine. Furthermore it is not clear what type should be the sensors detecting the skimmer.

### ESSENCE OF THE INVENTION

Object of the present invention is the protection of automatic terminal devices (ATMs, cash-points) from “skimming”, i.e. copying the information written on the magnetic bank cards and finding out their PIN codes. Besides, the present invention is applicable for protection against all skimming methods known till now.

It is generally known that any electronic device is a source of electromagnetic emission interference (EMI). The spectrum of this emission depends on a number of factors among which operating time frequency, mechanical circuitry, element basis, topology of the printed-circuit card and others. It is sufficient that this electromagnetic field is received, amplified and analyzed in a suitable manner in order to detect any operating electronic devices. It will be even easier if a particular type of device is sought and if the particular characteristics of this device are known. The spectrum of this emission resembles white noise but it has also strongly presented peaks in the frequencies of the clock signal and its lower and higher harmonics (even and odd). All this happens in the frequency band from several tens of Hz up-to over 100 Hz.

Usually the recording devices are constructed on the basis of micro controller and Flash memory. Even if such devices are well screened these two elements emit very high EMI.

In order to time synchronize data any skimming device needs some kind of real time clock (RTC). Almost 100% of these clocks (either part of some micro controller or a separate unit) operate with clock frequency 32768 Hz. This means that there will be a peak at this frequency in the spectrum of their electromagnetic emission. Such a peak is present also in the contemporary skimming devices made of single chip micro controllers.

The locations on the automatic teller machine suitable for mounting of skimming devices could be determined sufficiently definitely. These are the area around the bank card slot, around, beside or above the keyboard for entering the PIN code, the decorative outside panel of the ATM under the keyboard for entering the PIN code.

According to the method of protection against skimming of the present invention sensors are mounted on locations throughout the ATM that are suitable for mounting of skimming devices but these sensors are mounted on the internal side of the automatic teller machine. These sensors are connected to a control module controlling their operation and analyzing the information input by them, and if necessary sending a signal to a notifying module. It is a great advantage of the invention that on the ATM's body there are no visible elements that could give a hint that this ATM is protected.

The present invention provides a method for detection of devices stealing information (skimming devices), the method comprising detection of electromagnetic emission by means of sensors mounted on the inner wall of an automatic teller machine (ATM), and scanning for presence of electromagnetic emission above a threshold and sending an alarm signal upon detecting such an emission, wherein the electromagnetic emission is scanned by sensors that are specially developed for implementing the method of the present invention, in a wide frequency band from 10 kHz to 30 MHz and a narrow frequency band, wherein in the narrow frequency band only one determined frequency is passed through filters and the input from the sensors is analyzed and processed with an algorithm according to the invention using a threshold upon reaching which is generated an alarm signal, the threshold being chosen in such a manner that it does not obstruct the discriminating between the useful signal and the interferences.

The method according to the invention is implemented by a device according to the invention comprising sensors for detecting electromagnetic emission, micro controllers for controlling said sensors, a master micro controller for processing data input by said sensors and a notifying module sending a signal to a control center.

According to the invention a sensor is provided for detection of electromagnetic emission comprising a receiving part consisting of a planar inductive antenna with high own resonance frequency and surface depending on the location monitored for presence of a skimming device; an amplifying part representing a low-noise preamplifier having high input impedance and differential input; a regulating part in the form of a circuit for digital regulating of the gain controlled by a micro controller via digital-to-analog converter with certain resolution; a filtering part comprising a broadband channel and a narrowband channel and a converting part made of a logarithmic converter with detector having large dynamics for conversion of the input high frequency voltage into a permanent voltage according to a logarithmic principle.

According to the invention an algorithm is provided for implementation of the method for detection of devices stealing information (skimming devices) according to the invention.

Hereinafter the invention will be clarified in detail with reference to the accompanying drawings.

### SHORT DESCRIPTION OF THE FIGURES

FIG. 1 illustrates a cross section of an automatic teller machine with mounted skimming device and sensor of the device for protection against skimming according to the invention.

FIG. 2 illustrates a schematic diagram of the device for protection against skimming according to the invention.

FIG. 3 illustrates a schematic diagram of a sensor of the device for protection against skimming according to the invention.

FIG. 4 illustrates an algorithm of the program controlling the operation of the sensor (recorded on a single chip micro controller which is separate for each sensor).

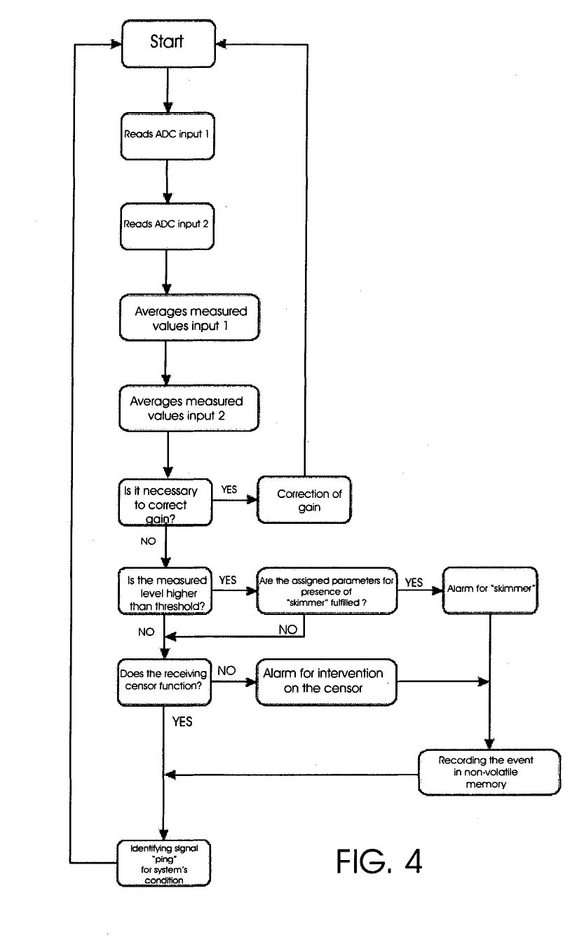

### EMBODIMENTS OF THE INVENTION

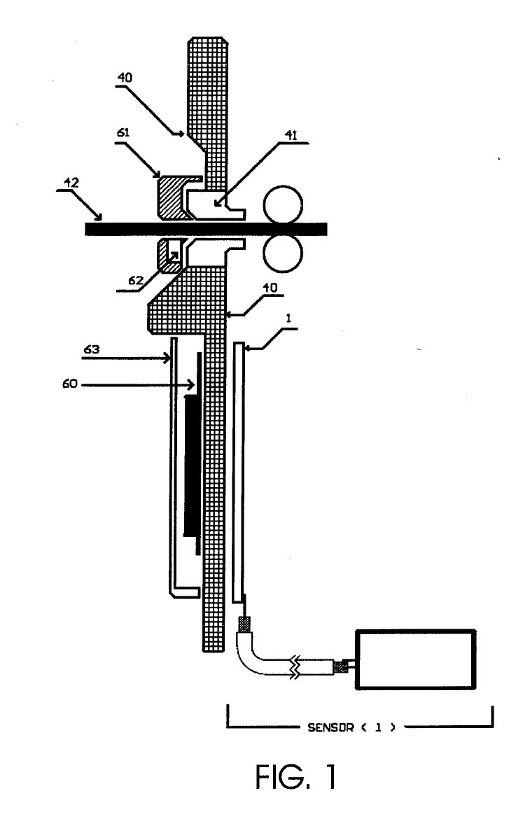

FIG. 1 illustrates a cross-section of an automatic teller machine 40 with skimming device 60 having a “false mouth” 61 mounted on the bank card slot 41 of the automatic teller machine 40. The skimming device has a magnetic head 62 reading the track 2 of a magnetic card 42 which will be copied by the skimming device 60. The recording electronics of the skimming device 60 is concealed by a false panel 63 located in front of the recording electronics and resembling an outer decorative element of the teller machine 40. In the bottom part of the teller machine 40 directly behind the outer decorative element 63 is located a planar receiving module 13 which is part of a sensor 1 of the system for protection according to the present invention.

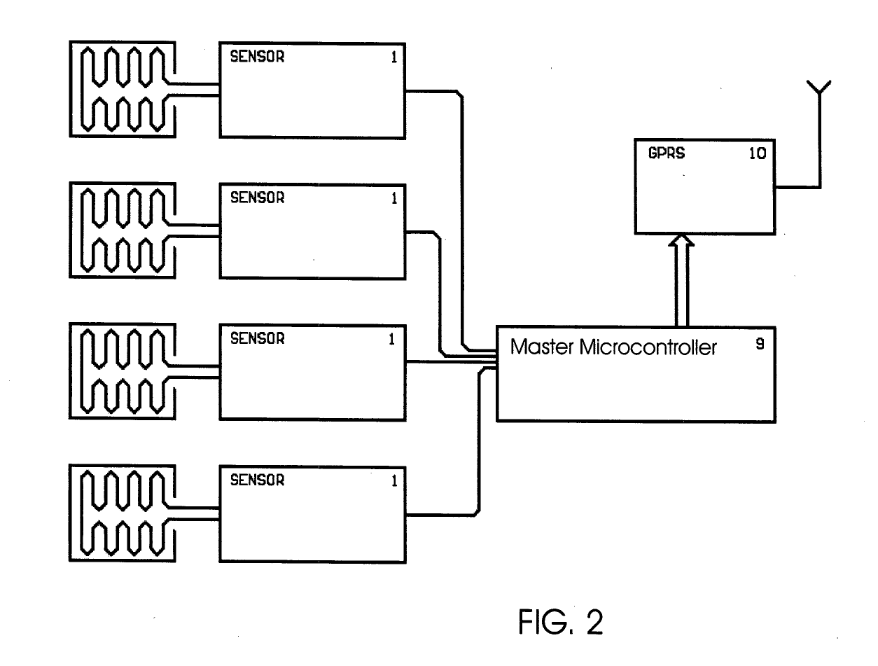

FIG. 2 illustrates a schematic diagram of a device for protection against skimming according to the present invention. The device consists of sensors detecting the presence of electromagnetic emission 1 (located behind the areas on which can be mounted skimming devices or on which usually are mounted such skimming devices), a master micro controller 9 controlling the sensors and processing their input, and a notifying module 10 sending a signal to a control center.

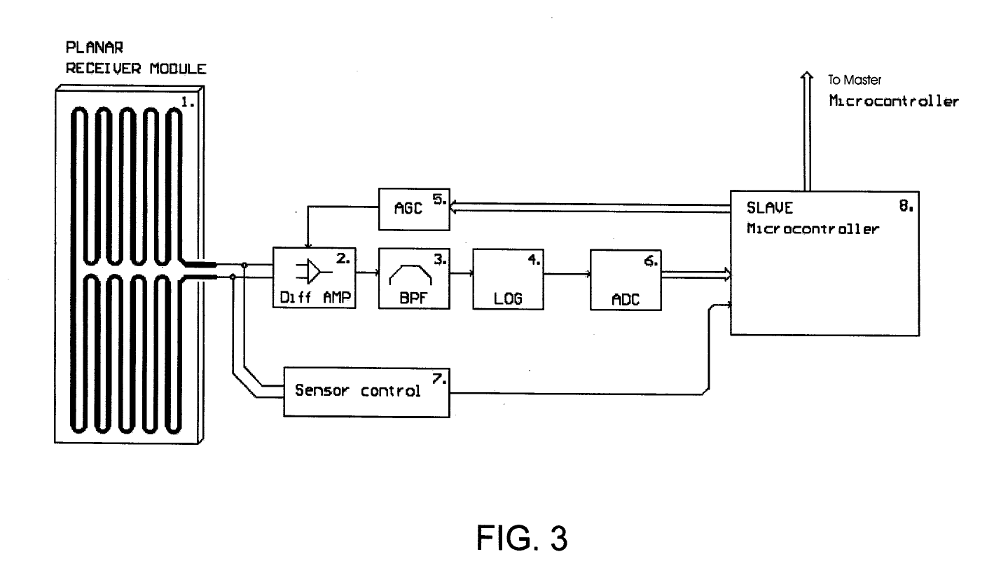

FIG. 3 illustrates a schematic diagram of sensor 1 for detection of electromagnetic emission. The receiving part of the sensor represents a planar (e.g. made of material FR4) inductive antenna 13 with high own resonance frequency (over 30 MHz) and surface depending on the location monitored for presence of skimming device. This technology (the planar technology) allows great technological compliance and recurrence of the parameters. The received electromagnetic emissions (EMI) are amplified by a low-noise preamplifier 2 (Diff AMP) with high input impedance and differential input constructed according to an instrumental amplifier scheme. Using a differential scheme of connecting allows the suppression of the interfering synphase signal with more than 70 dB. A possibility of electronic regulation of the gain 5 (AGC, GAIN CONTROLL) is provided which is carried out digitally and is controlled by a micro controller 8 via a digital-analog converter 11 (DAC). The frequency band of the preamplifier 2 is consistent with the spectrum of the useful signal (10 kHz to 30 MHz). The signal amplified in such a manner is sent to filters aiming to remove the signals without informative value which would obstruct the subsequent processing. This processing is carried out in two independent circuits—a broadband channel and a narrowband channel (for frequency 32768 kHz).

The broadband channel is constructed of band filter 3 (e.g. from Besel) with steepness from 18 dB/oct to 36 dB/oct, preferably 24 dB/oct. The steepness of the filter is preferably chosen to be 24 dB/oct because a lower steepness will not allow good filtering of the useless signals and a much higher steepness would lead to big phase distortions in the band of passage.

The narrowband channel represents a resonance band filter 12 (BPF) having a narrow band of passage (100 Hz) and high steepness in the band of fading (over 48 dB/oct). The passed frequency is 32768 kHz.

Downstream of each band filter 3 and 12 (BPF) is located a logarithmic converter with detector 4 (LOG) whose purpose is to convert the input high frequency voltage into a permanent voltage according to a logarithmic principle. In order to enable it to analyze a larger dynamic range of emissions the dynamics of the logarithmic converter with detector 4 has a higher value in the range between 80 dB to 120 dB, preferably 120 dB. Such a logarithmic converter with detector is, e.g. the integral circuit AD8703 from Analog Devices, USA. This approach to the technical circuitry guarantees an unequivocal detection of devices with very low EMI level.

In the sensor is used a circuit for adjusting the gain 5 (GAIN CONTROLL) by means of which the micro controller 8 changes dynamically the gain of the input preamplifier 2 (Diff AMP) in such a manner that its output level is within the band of the analog-digital converter 6 (ADC). This is achieved by means of digital-analog converter 11 (DAC) with resolution 10 bits (1024 discrete values).

The threshold over which is triggered the automatic regulation of the gain is chosen in such a manner that this does not obstruct the differentiation of the useful signal from the interference. As such threshold is chosen the EMI level of the most often used skimmers.

The time for establishing the circuit for regulation of the gain 5 (GAIN CONTROLL) also is changed dynamically and depends on the level of the signal. In case of a high level this time is short and vice versa—the time is increasing with the decreasing of the signal level. This process is carried out entirely by the micro controller 8 by means of a program algorithm for gain control.

When the useful electromagnetic signal in the form of permanent voltage is received by the planar receiving module, and then amplified, filtered and detected, this signal is sent to the input of the analog-digital converter 6 (ADC) operating according to the principle of sequential approximations and resolution 12 bits which converts the signal into discrete form. The signals from the broadband and narrowband channels are sent to different channels of the analog-digital converter. The digital data is sent to the micro controller 8 and is processed by the program algorithm.

In case of detection of an electromagnetic emission corresponding to the predetermined parameters the micro controller 8 sends a signal to the master micro controller 9. The master micro controller 9 receives information from all sensors, processes this information and generates a control signal for presence of a skimmer, the generated signal being sent to an alarm module 10 (GPRS).

Hereinafter will be described the steps of the program algorithm carried out by the micro controller 8.
1) Reading the information from ADC at determined intervals of time and storing the read data in an inner memory RAM (buffer memory for data). The information about the broadband channel (input 1 of ADC) and narrowband channel for frequency 32768 kHz (input 2 of ADC) is read sequentially. The data is stored in independent cells of the memory.
2) Executing a subprogram for averaging the read results in order to decrease the interference. The subprogram adds N number of sequentially measured values and divides the resulting sum by this number (N). The resulting mean value is accepted as filtered. The signals from the broadband and narrowband channels are processed separately and independently.
3) Analyzing the level of the received signal and introducing a correction of the gain of the input preamplifier 2 by means of the circuit for gain control. At low levels of the signal the gain is not corrected. In case 50% of the measured band of the analog-digital converter 6 (ADC) is reached, the gain of the preamplifier 2 (Diff AMP) is reduced step-like with increment depending on the resolution of the digital-analog converter 11 (DAC). This increment is 1/1024 if the converter has a resolution of 10 bits. Thus the high levels of electromagnetic emission are measured without overfilling the readings of ADC 6.
4) Comparing the result of the measurement to a predetermined threshold called provisionally “noise level”. Generally this is the total level of all signals without informative value that will not be taken into consideration (e.g. the level of the own emission of the ATM, surrounding emissions depending on the location of the ATM, electromagnetic smog etc). This level can be introduced as a constant or could be amended in an adaptive manner depending on the specific features of the application.
5) Triggering a subprogram for analyzing a detected signal exceeding the noise level. The monitored parameters are, for example, signal level, signal changes, signal duration, signal spectrum and the like. The signal of the narrowband channel has the higher priority.
6) The micro controller records in a non-volatile memory the time and date of each event that provoked the generating of an alarm signal. This information can be read only in service regime by authorized persons.
7) The micro controller continually monitors the permanent current parameters (e.g. ohm resistance) of the planar receiving inductivity via a circuit 7 and thus the micro controller detects mechanical interventions disturbing its integrity.
8) Generating an alarm signal and sending it to the master micro controller 9 in case the assigned parameters are fulfilled (i.e. a skimming device or intervention on the receiving part is detected).
9) At determined time intervals sending an identification signal (‘ping”) to the master micro controller used to monitor the integrity of the system sensors—master micro controller.

The master micro controller receives a signal from each of the sensors and in case one or more of these sensors send(s) a signal for detection of a skimmer, the master micro controller generates an alarm signal sent via a radio transmitter, GSM/GPRS module or in other alternative manner to an information center. In an alternative embodiment of the invention along with the alarm signal a signal for discontinuing the ATM operations is generated.

On the other hand the notifying module also monitors the connection between the master micro controller 9 and the availability of energy supply. If this connection is disturbed a service alarm signal is sent to the information center. The same (but with another code) happens when the energy supply is not present. The control center monitors the existence of a continuous connection with the communication module by means of a “ping” sent at determined time intervals. The purpose of this is protection against jamming of the communication channel by a jammer (device making noise in the communication band).

The present patent specification discloses exemplary embodiments of the device, method, algorithm and sensor according to the invention and by no means should be interpreted as limiting the scope of the present invention which should be accorded the broadest protection in accordance with the accompanying claims.

1. Method for detection of devices stealing information (skimming devices) comprising detection of electromagnetic emission by means of sensors mounted on the inside of an automatic teller machine (ATM) and monitoring the parameters of the medium for any change through the change of a parameter showing the threshold level of the electromagnetic emission and sending an alarm signal upon passing over the said threshold level, characterized in that the electromagnetic emission is monitored by sensors (1) according to the invention, in a broadband from 10 kHz to 20 MHz and a narrowband, only one determined frequency being passed through filters in the narrowband, in that the output of the sensors (1) are analyzed and processed according to an algorithm of the invention using a threshold value upon reaching of which an alarm signal is generated and the threshold value is selected in such a manner that it does not obstruct the discrimination between the useful signal and interference.

2. Method according to claim 1, comprising steps of
continual scanning of electromagnetic emissions;
processing of obtained data;
recording data;
generating an alarm signal and/or signal for discontinuation of ATM operations;
characterized in that
the said continual scanning of the electromagnetic emissions is carried out in the frequency band from 10 kHz to 30 MHz;
obtained data is amplified by a preamplifier (2) with high input impedance and differential input for suppression of interfering synphase signals and after that the said data is converted by an analog-digital converted (6);
the amplified data is divided into broadband channel and narrowband channel and after that the said amplified data is filtered to remove signals without informative value;
the said processing of said obtained data comprises processing for decreasing the interference and processing for analyzing the level of the received signal;
on the basis of said analyzed signal is introduced a correction of the gain of said preamplifier (2) in order to measure effectively the high levels of electromagnetic emission without overfilling of the readings of said analog-digital preamplifier (6);
said analyzed signal is monitored for fulfillment of pre-assigned parameters regarding the signal level and said signal is compared with a pre-determined threshold value called “noise level”;
said recording of data is recording of the time and date of each alarm signal generating event and said data is recorded in a non-volatile memory;
continuous sending of an identification signal “ping” in order to monitor the integrity of the system sensors (1)—master micro controller (9);
continuous monitoring by a micro controller (8) of permanent current parameters of a planar receiving inductivity (13) in order to intercept mechanical interventions on its integrity.

3. Method according to claims 1 and 2, characterized in that using a differential scheme of connecting the preamplifier (2) allows the suppression of interfering synphase signals over 79 dB.

4. Method according to claims 1 and 2, characterized in that filtering in a broadband channel is performed by one or more band filters (3) with a definite steepness.

5. Method according to claim 4, characterized in that the steepness of said band filters (3) is from 18 dB/oct to 36 dB/oct.

6. Method according to claims 4 and 5, characterized in that the steepness of said band filters (3) is 24 dB/oct.

7. Method according to claims 1 and 2, characterized in that filtering in a narrowband channel is performed by a resonance band filter (12) with narrow pass band of 100 Hz and high steepness in the fading band.

8. Method according to claim 7, characterized in that the steepness of the resonance band filter (12) in the fading band is more than 48 dB/oct.

9. Method according to claims 7 and 8, characterized in that the passed frequency in the pass band is 32768 Hz.

10. Method according to claims 1 and 2, characterized in that the processing for decreasing interference comprises averaging the read results by means of adding N number of sequentially measured values and dividing the resulting sum by N.

11. Method according to claims 1, 2 and 10, characterized in that the processing of the signals from the broadband channel and those from the narrowband channel is carried out separately and independently.

12. Method according to claims 1 and 2, characterized in that the processing for analyzing the level of the received signal comprises comparing the level of the received signal with pre-assigned threshold value of a “noise level”.

13. Method according to claims 1, 2 and 12, characterized in that the said “noise level” is the total level of all signals without informative value which will not be taken into consideration.

14. Method according to claims 1, 2, 12 and 13, characterized in that the said noise level depends on the level of the own emission of the ATM, the surrounding emissions depending on its location, electromagnetic smog and other parameters defined by the environment of the ATM's location.

15. Method according to claims 1, 2, 12, 13 and 14, characterized in that the said noise level is pre-determined as a constant value.

16. Method according to claims 1, 2, 12, 13 and 14, characterized in that the said noise level is changed adaptively and in accordance with the particular characteristics of the ATM's location.

17. Method according to claims 1 and 2, characterized in that the parameters for analyzing the signal level for fulfillment of pre-defined parameters of the signal level are the level of the signal, change of the signal, duration of the signal, spectrum of the signal and other parameters suitable for the particular application.

18. Method according any preceding claims, characterized in that the signal of the narrowband channel is processed and analyzed with a higher priority.

19. Method according to claims 1 and 2, characterized in that alarm signal generating events recorded in the non-volatile memory can be read only in a service regime by authorized persons.

20. Method according to claims 1 and 2, characterized in that the micro controller (8) monitors continually the permanent current parameters of the planar receiving inductivity (13) of the sensors (1) by means of the circuit (7).

21. Method according to claims 1, 2 and 20, characterized in that the micro controller (8) monitors continually the ohm-resistance of the planar receiving inductivity (13) of the sensors (1) by means of the circuit (7).

22. Device for detection of devices stealing information (skimming devices), comprising sensors for electromagnetic emissions, characterized in that the said sensors are one or more sensors (1) according to the invention and in that the device comprises also a master micro controller (9) for control of the sensors and processing the output of the said sensors (1), and a notifying module (10) sending a signal to a control center in case of presence of electromagnetic emissions with a level exceeding the said “noise level”.

23. Device according to claim 22, characterized in that the notifying module (10) is a radio transmitter.

24. Device according to claim 22, characterized in that the notifying module (10) is a GPRS.

25. Sensor for detection of electromagnetic emissions comprising a receiving part, characterized in that the receiving part is a planar inductive antenna (13) with high own resonance frequency and surface depending on the location monitored for presence of a skimming device, and in that the sensor comprises also an amplifying part representing a preamplifier (2) with high input impedance and differential input; a regulating part representing a circuit for regulating the gain (5) digitally, the said circuit being controlled by a micro controller (8) by means of digital-analog converter (11) with definitive resolution; a filtering part comprising a broadband channel and a narrowband channel; and a converting part comprising a logarithmic converter with detector (4) having a large value of the dynamics for converting the input high frequency voltage to a permanent voltage according to a logarithmic principle.

26. Sensor according to claim 25, characterized in that the inductive antenna (13) is made of material FR4.

27. Sensor according to claim 25, characterized in that the preamplifier (2) is a low-noise preamplifier with frequency band that is consistent with the spectrum of the useful signal.

28. Sensor according to claims 25 and 27, characterized in that the spectrum of the useful signal is from 10 kHz to 30 MHz.

29. Sensor according to claim 25, characterized in that the resolution of the digital-analog converter (11) is from 10 to 24 bits.

30. Sensor according to claim 25, characterized in that the resolution of the digital-analog converter (11) is 16 bits.

31. Sensor according to claim 25, characterized in that the narrowband channel represents a resonance band filter (12) with narrow pass band and high steepness in the fading band.

32. Sensor according to claims 25 and 31, characterized in that the pass band is 100 Hz.

33. Sensor according to claims 25 and 31, characterized in that the steepness of the fading band is higher than 48 dB/oct.

34. Sensor according to claims 25 and 32, characterized in that the passed frequency is 32768 Hz.

35. Sensor according to claim 25, characterized in that the dynamics of the logarithmic converter with detector (4) has a high value in the range of 80 dB to 120 dB.

36. Sensor according to claim 25, characterized in that the dynamics of the logarithmic converter with detector (4) is 120 dB.

37. Algorithm for carrying out of a method for detection of devices stealing information (skimming devices) in accordance with claims 1 to 20.
